(19) United States
(12) Patent Application Publication
(10) Pub. No.: US 2025/0126767 A1
(43) Pub. Date: Apr. 17, 2025

(54) MULTI-PATTERN TOOLING PLATE

(71) Applicant: ILLINOIS TOOL WORKS INC., Glenview, IL (US)

(72) Inventors: Scott A. Reid, Bradford, MA (US); Guohua Liu, Jiangsu (CN)

(21) Appl. No.: 18/688,543

(22) PCT Filed: Nov. 12, 2021
(86) PCT No.: PCT/CN2021/130258

§ 371 Date: Mar. 1, 2024

(51) Int. Cl. H05K 13/00; H05B 3/06; H05K 13/04

(52) U.S. Cl. CPC H05K 13/0069; H05B 3/06; H05K 13/0465

(57) ABSTRACT

Heated chuck plates and apparatus using the same where a heated chuck or tooling plate has a body including an external surface, the body configured to secure an electronics assembly near the external surface, and an air channel network configured to selectively direct heated air to a plurality of predetermined locations on the electronics assembly, the air channel network including: a first heating pathway configured to direct the heated air through the external surface and onto a first location of the plurality of predetermined locations, and a second heating pathway configured to direct the heated air through the external surface and onto a second location of the plurality of predetermined locations.

### BACKGROUND OF THE DISCLOSURE

### 1. Field of the Disclosure

The present disclosure relates to heated chuck plates for solder dispensers.

### 2. Discussion of Related Art

There are several types of dispensing systems used to dispense precise amounts of liquid or paste for a variety of applications. One such application is the assembly of integrated circuit chips and other electronic components onto circuit board substrates. In this application, automated dispensing systems are used for dispensing dots of liquid epoxy or solder paste, or some other related material, onto circuit boards. Automated dispensing systems are also used for dispensing lines of underfill materials and encapsulents, which may be used to mechanically secure components to the circuit board. Exemplary dispensing systems described above include those manufactured and distributed by ITW EAE of Glenview, Illinois under the brand name CAMALOT®.

In a typical dispensing system, a heated chuck is used to hold an electronic substrate in place as the electronic substrate is heated. One issue associated with heated chucks is that they include surfaces with holes designed to channel hot air in one particular heating pattern on the electronic substrate, which necessitates replacing the chuck for every different substrate needing a different heating pattern. One solution is to apply infrared heating to the entire substrate, thereby covering all possible heating patterns. However, this method is inefficient and unnecessarily heats areas of the board that do not require heating at the time, thereby potentially altering or even damaging previous soldering or other work done to the substrate.

Another issue is that the chuck becomes so hot that replacing it for a different heating pattern during manufacturing requires either handling a very hot piece of equipment, which is potentially dangerous to the people performing the work, or waiting for a period of time for the top plate to cool down before replacement, which adds costly downtime between dispensing cycles.

What is needed is a heated chuck plate that can be easily modified to switch between different heating patterns, is safe to use, and does not add significant time to manufacturing processes using dispensing systems.

### SUMMARY OF THE DISCLOSURE

Featured in one example is a heated chuck plate that is reconfigurable for more than one heating pattern, is safe to use, and does not add significant time to the process of manufacturing electronic assemblies in dispensing systems.

According to at least one embodiment there is provided an apparatus for depositing an assembly material on an electronic substrate, the apparatus comprising a frame, an assembly applicator coupled to the frame, the assembly applicator being configured to apply assembly material on the electronic substrate, and a support assembly coupled to the frame, the support assembly being configured to support the electronic substrate, the support assembly including a heated chuck plate including a body including an external surface, the body configured to secure the electronic substrate near the external surface, and an air channel network configured to selectively direct heated air to a plurality of predetermined locations on the electronic substrate, the air channel network including a first heating pathway configured to direct the heated air through the external surface and onto a first location of the plurality of predetermined locations, and a second heating pathway configured to direct the heated air through the external surface and onto a second location of the plurality of predetermined locations.

In one example, the air channel network includes a plurality of holes in the external surface of the body of the heated chuck plate, the first heating pathway includes a first set of the plurality of holes, and the second heating pathway includes a second set of the plurality of holes.

In another example, the first set of the plurality of holes includes a first grouping of the plurality of holes positioned to direct the heated air onto the first location of the plurality of predetermined locations on the electronic substrate, and the second set of the plurality of holes includes a second grouping of the plurality of holes positioned to direct the heated air onto the second location of the plurality of predetermined locations on the electronic substrate.

In one example, the first set of the plurality of holes includes a third grouping of the plurality of holes positioned to direct the heated air onto a third location of the plurality of predetermined locations on the electronic substrate, and the second set of the plurality of holes includes a fourth grouping of the plurality of holes positioned to direct the heated air onto a fourth location of the plurality of predetermined locations on the electronic substrate.

In another example, the first set of the plurality of holes includes a fifth grouping of the plurality of holes positioned to direct the heated air onto a fifth location of the plurality of predetermined locations on the electronic substrate, and the second set of the plurality of holes includes a sixth grouping of the plurality of holes positioned to direct the heated air onto a sixth location of the plurality of predetermined locations on the electronic substrate.

In one example, the air channel network further includes at least one port configured to selectively permit the heated air into one of the first heating pathway and the second heating pathway.

In another example, the at least one port includes a first port configured to selectively permit the heated air into the first heating pathway and a second port configured to selectively permit the heated air into the second heating pathway.

In one example, the first port is configured to receive a first set screw, the first set screw blocking the heated air from traveling through the first heating pathway when the first set screw is tightened and permitting the heated air to travel through the first heating pathway when the first set screw is loosened, and the second port is configured to receive a second set screw, the second set screw blocking the heated air from traveling through the second heating pathway when the second set screw is tightened and permitting the heated air to travel through the second heating pathway when the second set screw is loosened.

In another example, the air channel network further includes a third heating pathway configured to receive the heated air regardless of any position of the first set screw in the first port and regardless of any position of the second set screw in the second port.

In one example, the apparatus further comprises a plurality of holding members configured to releasably secure the electronic substrate to the heated chuck plate.

In another example, the apparatus further comprises a first mask including at least one hole positioned in the first mask to direct the heated air from the first heating pathway onto at least one location of the plurality of predetermined locations on the electronic substrate.

In one example, the first mask, except for the at least one hole, is configured to block the heated air from directly encountering the electronic substrate.

In another example, the at least one hole includes a first hole positioned in the first mask to direct the heated air from the first heating pathway onto the first location of plurality of predetermined locations on the electronic substrate, and a second hole positioned in the first mask to direct the heated air from the second heating pathway onto the second location of the one or more predetermined locations on the electronic substrate.

In one example, the first mask includes a grasping portion for removing the first mask from the external surface, the grasping portion extending over an edge of the external surface.

In another example, the apparatus further comprises a second mask including at least one hole positioned in the second mask to direct the heated air from the second heating pathway onto at least one location of the plurality of predetermined locations on the electronic substrate.

In one example, the first mask is constructed from a material including one of metal, rubber, silicone, or mylar.

In another example, the apparatus further comprises a valve configured to selectively direct the heated air into one of the first heating pathway and the second heating pathway.

In one example, the valve is electronically controlled by an external controller, pneumatically controlled by the external controller, or mechanically controlled by one of a set screw, a knob, and a switch.

According to at least one embodiment there is provided a heated chuck plate comprising a body including an external surface, the body configured to secure an electronics assembly near the external surface, and an air channel network configured to selectively direct heated air to a plurality of predetermined locations on the electronics assembly, the air channel network including a first heating pathway configured to direct the heated air through the external surface and onto a first location of the plurality of predetermined locations, and a second heating pathway configured to direct the heated air through the external surface and onto a second location of the plurality of predetermined locations.

In one example, the air channel network includes a plurality of holes in the external surface of the body of the heated chuck plate, the first heating pathway includes a first set of the plurality of holes, and the second heating pathway includes a second set of the plurality of holes.

In another example, the first set of the plurality of holes includes a first grouping of the plurality of holes positioned to direct the heated air onto the first location of the plurality of predetermined locations on the electronics assembly, and the second set of the plurality of holes includes a second grouping of the plurality of holes positioned to direct the heated air onto the second location of the plurality of predetermined locations on the electronics assembly.

In one example, the first set of the plurality of holes includes a third grouping of the plurality of holes positioned to direct the heated air onto a third location of the plurality of predetermined locations on the electronics assembly, and the second set of the plurality of holes includes a fourth grouping of the plurality of holes positioned to direct the heated air onto a fourth location of the plurality of predetermined locations on the electronics assembly.

In another example, the first set of the plurality of holes includes a fifth grouping of the plurality of holes positioned to direct the heated air onto a fifth location of the plurality of predetermined locations on the electronics assembly, and the second set of the plurality of holes includes a sixth grouping of the plurality of holes positioned to direct the heated air onto a sixth location of the plurality of predetermined locations on the electronics assembly.

In one example, the air channel network further includes at least one port configured to selectively permit the heated air into one of the first heating pathway and the second heating pathway.

In another example, the at least one port includes a first port configured to selectively permit the heated air into the first heating pathway and a second port configured to selectively permit the heated air into the second heating pathway.

In one example, the first port is configured to receive a first set screw, the first set screw blocking the heated air from traveling through the first heating pathway when the first set screw is tightened and permitting the heated air to travel through the first heating pathway when the first set screw is loosened, and the second port is configured to receive a second set screw, the second set screw blocking the heated air from traveling through the second heating pathway when the second set screw is tightened and permitting the heated air to travel through the second heating pathway when the second set screw is loosened.

In another example, the air channel network further includes a third heating pathway configured to receive the heated air regardless of any position of the first set screw in the first port and regardless of any position of the second set screw in the second port.

In one example, the heated chuck plate further comprises a valve configured to selectively direct the heated air into one of the first heating pathway and the second heating pathway.

In another example, the valve is electronically controlled by an external controller, pneumatically controlled by the external controller, or mechanically controlled by one of a set screw, a knob, and a switch.

### BRIEF DESCRIPTION OF THE DRAWINGS

Various aspects of at least one embodiment are discussed below with reference to the accompanying figures, which are not intended to be drawn to scale. The figures are included to provide an illustration and a further understanding of the various aspects and embodiments, and are incorporated in and constitute a part of this specification, but are not intended as a definition of the limits of any particular embodiment. The drawings, together with the remainder of the specification, serve to explain principles and operations of the described and claimed aspects and embodiments. In the figures, each identical or nearly identical component that is illustrated in various figures is represented by a like numeral. For purposes of clarity, not every component may be labeled in every figure. In the figures:

FIG. 1 is a block diagram of a dispensing system and external air source according to aspects described herein;

FIG. 2 is a schematic view of a dispensing system according to aspects described herein;

FIG. 3 is an exploded perspective view of a chuck including a heated chuck plate according to aspects described herein;

FIG. 4A is a top view of an air channel network in a heated chuck plate according to aspects described herein;

FIG. 4B is a top view of an air channel network in a heated chuck plate according to aspects described herein;

FIG. 5A is a top view of an air channel network in a heated chuck plate according to aspects described herein;

FIG. 5B is a top view of an air channel network in a heated chuck plate according to aspects described herein;

FIG. 6 is a top plan view of a mask for a heated chuck plate according to aspects described herein;

FIG. 7 is a top plan view of a mask for a heated chuck plate according to aspects described herein; and

FIG. 8 is a perspective view of a dispensing system with packaging removed to disclose a pre-heat station, a dispense station and a post-heat station.

### DETAILED DESCRIPTION OF THE DISCLOSURE

For the purposes of illustration only, and not to limit the generality, the present disclosure will now be described in detail with reference to the accompanying figures. This disclosure is not limited in its application to the details of construction and the arrangement of components set forth in the following description or illustrated in the drawings. The principles set forth in this disclosure are capable of other embodiments and of being practiced or carried out in various ways. Also, the phraseology and terminology used herein is for the purpose of description and should not be regarded as limiting. Any references to examples, embodiments, components, elements or acts of the systems and methods herein referred to in the singular may also embrace embodiments including a plurality, and any references in plural to any embodiment, component, element or act herein may also embrace embodiments including only a singularity. References in the singular or plural form are not intended to limit the presently disclosed systems or methods, their components, acts, or elements. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms. In addition, in the event of inconsistent usages of terms between this document and documents incorporated herein by reference, the term usage in the incorporated reference is supplementary to that of this document; for irreconcilable inconsistencies, the term usage in this document controls.

The present disclosure is directed to heated chuck plates for dispensing systems and in particular, reconfigurable heated chuck plates that are part of heated chuck for dispensing systems. A chuck is a specialized type of clamp used to hold an object with radial symmetry. In printed circuit board manufacturing, for example, chucks are used to hold electronic substrates in place when they are being heated before solder or other materials are applied.

During the manufacture of electronic assemblies and electronic substrates, such as printed circuit boards, it is often required to apply heat, sometimes upwards of 150° C. to locations on the board before solder paste or other materials is dispensed onto the area. Heating operations may occur before, during, and after each dispensing cycle. For example, some locations may require being heated prior to dispensing underfill. “Non-contact” convection heating is used to impinge the board with heated air which is usually focused in the areas required most. Inferred heating can also be used, but heats the entire area of the board, which is both unnecessary and potentially damaging.

Certain manufacturing processes and applications must be able to accommodate electronic substrates having different arrangements/layouts of components (e.g., surface mount electrical components, through-hole electrical components, capacitors, resistors, chip packages, BGA chips, etc.). Furthermore, different electronic substrates or even the same electronic substrate may require different locations or zones to be heated at different times. With all of this variability, the efficiency of dispensing cycles diminishes due a different chuck plate (also referred to as a tooling plate or a top plate) having to be designed and built for each substrate and heating pattern. Efficiency also dwindles due to the chuck plate being too hot to handle safely, thus either having to be changed over while hot or allowed to cool down. Neither the repeated re-designing or the cooling downtime are desired for quick manufacturing changeover.

Embodiments of the present disclosure include heated chuck plates for dispensing systems that are reconfigurable for more than one heating pattern, are safe to use, and do not add significant time to the process of manufacturing electronic substrates in dispensing systems. Although dispensing systems are described, the concepts described herein can be applied to other types of printed circuit board fabrication equipment, such as stencil printers. Further, though described herein as being included in dispensing systems, it is also contemplated that embodiments are applicable to devices that do not dispense solder paste or other similar materials. For example, the reconfigurable chuck plates described herein may be used in devices that only require heating components in a chuck as part of another process.

By implementing the principles of the present disclosure, a deposition system can easily switch between dispensing cycles for different heating patterns on electronic substrates held in a heated chuck without posing a safety risk to operators and without adding significant time to the process of manufacturing electronics assemblies in dispensing systems.

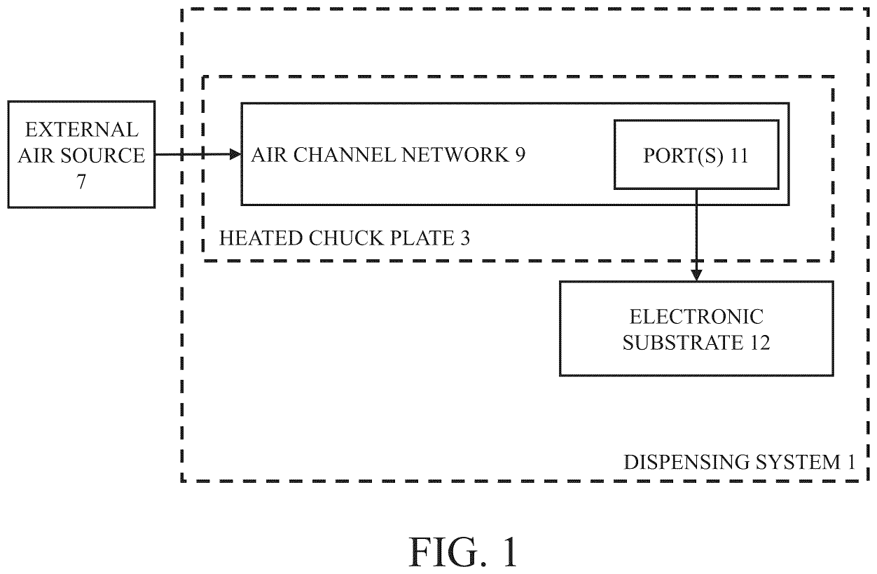

FIG. 1 shows the arrangement of a dispensing system 1 that includes a heated chuck plate 3. The heated chuck plate 3 includes an air channel network 9, which channels/guides heated air from an external air source 7 through holes in an external surface of the heated chuck plate 3 and onto one or more predetermined locations on an electronic substrate 12. The electronic substrate 12 is, in certain examples, a printed circuit board.

To permit or block the heated air from reaching the one or more locations on the substrate 12, one or more ports 11 are provided in the heated chuck plate 3. The ports 11, in certain examples, are configured to receive set screws that may be loosened or tightened by an operator using an appropriate tool such as a hex wrench, screwdriver, or the like. By adding a small and specific point of contact that is engageable by an operator using a tool to gain a safe separation distance between the heated chuck plate 3 and the operator's body, the operator can safely and easily alter the air channel network 9 to channel the heated air to one or more heating pathways towards the one or more locations on the electronic substrate 12 via one or more corresponding locations (including the holes) on the surface of the chuck plate 3.

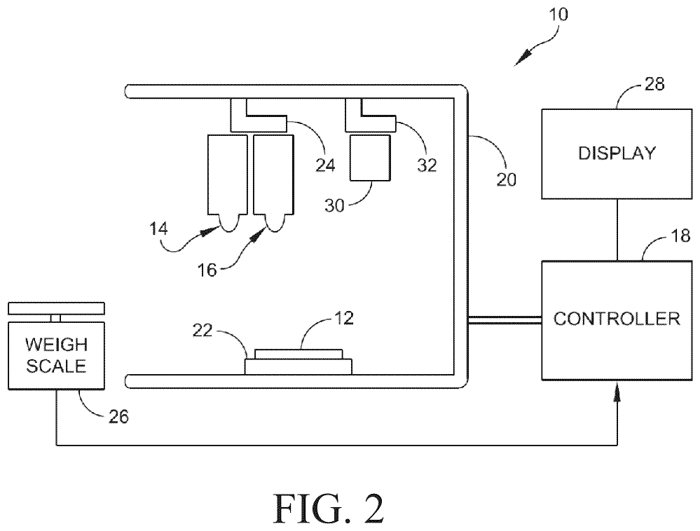

For purposes of illustration, embodiments of the present disclosure will now be described with reference to a dispensing system, generally indicated at 10, according to one embodiment of the present disclosure. Referring to FIG. 2, the dispensing system 10 is used to dispense a viscous material (e.g., an adhesive, encapsulent, epoxy, solder paste, underfill material, etc.) or a semi-viscous material (e.g., soldering flux, etc.) onto the electronic substrate 12. The electronic substrate 12 is, in certain examples, a printed circuit board (“PCB”) or a semiconductor wafer. The dispensing system 10 may alternatively be used in other applications, such as for applying automotive gasketing material or in certain medical applications or for applying conductive inks. It should be understood that references to viscous or semi-viscous materials, as used herein, are exemplary and intended to be non-limiting. The dispensing system 10 includes one or more dispensing units, for example, first and second dispensing units, generally indicated at 14 and 16, respectively, and a controller 18 to control the operation of the dispensing system. It should be understood that dispensing units also may be referred to herein as dispensing pumps and/or dispensing heads. Although two dispensing units are shown, it should be understood that one dispensing unit or more than two dispensing units may be employed.

The dispensing system 10 may also include a frame 20 having a base or support 22 for supporting the electronic substrate 12, a dispensing unit gantry 24 movably coupled to the frame 20 for supporting and moving the dispensing units 14, 16, and a weight measurement device or weigh scale 26 for weighing dispensed quantities of the viscous material, for example, as part of a calibration procedure, and providing weight data to the controller 18.

In certain examples the support 22 is part of a support assembly including the heated chuck plate 3. In some examples, the dispensing units 14, 16 are part of an assembly applicator coupled to the frame 20, the assembly applicator being configured to apply assembly material on the electronic substrate 12 or the electronic substrate 12.

A conveyor system (not shown) or other transfer mechanism, such as a walking beam, may be used in the dispensing system 10 to control loading and unloading of electronic substrates to and from the dispensing system. The gantry 24 can be moved using motors under the control of the controller 18 to position the dispensing units 14, 16 at predetermined locations over the electronic substrate. The dispensing system 10 may include a display unit 28 connected to the controller 18 for displaying various information to an operator. There may be an optional second controller for controlling the dispensing units. Also, each dispensing unit 14, 16 can be configured with a Z axis sensor to detect a height at which the dispensing unit is disposed above the electronic substrate 12 or above a feature mounted on the electronic substrate. The Z axis sensor is coupled to the controller 18 to relay information obtained by the sensor to the controller.

Prior to performing a dispensing operation, as described above, the electronic substrate, e.g., the printed circuit board, must be aligned or otherwise in registration with a dispensing unit of the dispensing system. The dispensing system further includes a vision system 30, which, in one embodiment, is coupled to a vision system gantry 32 movably coupled to the frame 20 for supporting and moving the vision system. In another embodiment, the vision system 30 may be provided on the dispensing unit gantry 24. As described, the vision system 30 is employed to verify the location of landmarks, known as fiducials, or components on the electronic substrate. Once located, the controller can be programmed to manipulate the movement of one or more of the dispensing units 14, 16 to dispense material on the electronic substrate. In certain embodiments, the dispensing units 14, 16 dispense material on the electronic substrate as it is fixed over the heated chuck plate 3 or any other heated chuck plate described herein.

In one embodiment, the dispense operation is controlled by the controller 18, which may include a computer system configured to control material dispensing units. In another embodiment, the controller 18 may be manipulated by the operator. The controller 18 is configured to manipulate the movement of the vision system gantry 32 to move the vision system so as to obtain one or more images of the electronic substrate 12. The controller 18 further is configured to manipulate the movement of the dispensing unit gantry 24 to move the dispensing units 14, 16 to perform dispensing operations.

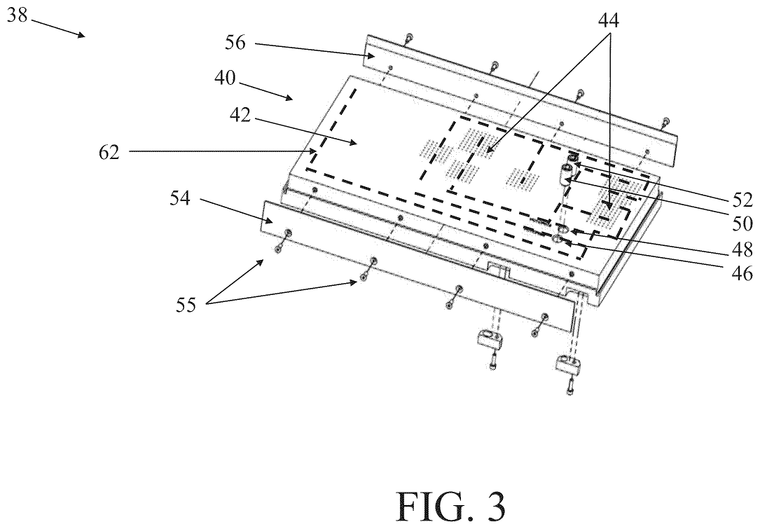

FIG. 3 shows an exploded view of a chuck generally indicated at 38 including a heated chuck plate having a body generally indicated at 40, a first holding member 54, and a second holding member 56. The holding members 54, 56 are arranged to move together with the body of the chuck 38 toward and away from the electronic substrate (e.g., the substrate 12) to secure the electronic substrate in place, and to position the substrate on or over an external, upper surface 42 of the heated chuck plate. The holding members 54, 56 collectively hold the electronic substrate in place on or over the external surface 42, with the holding members engaging opposite edges of the electronic substrate. The electronic substrate being ‘on’ the external surface 42 means the substrate and surface 42 are in direct physical contact. The electronic substrate being ‘near’ or ‘over’ the external surface means the substrate and the surface 42 are in close proximity such that the majority of the air leaving the holes 44 impinges on the corresponding location(s) on the substrate. In an example, the distance between the surface 42 and the substrate is between a few millimeters and up to 25 mm for underboard component clearance.

The first holding member 54 and the second holding member 56 are secured to the heated chuck plate 42 by a plurality of screws, each indicated at 55. To heat a printed circuit board, in an example, the printed circuit board (PCB) is held in place between a top clamp of a conveyor rail and a conveyor belt. In unison, the holding members 54, 56 and body 40 of the chuck 38 move up and towards the PCB, which is subsequently clamped between the top clamp(s) of the conveyor rail and the first and second holding members 54, 56. After being clamped, an air gap remains between the external surface 42 and the PCB.

The external surface 42 of the heated chuck plate includes several areas having a plurality of holes, each area indicated at 44, with the areas arranged in predetermined locations so that an air channel network 62 within the heated chuck plate channels hot air through the holes 44 and onto the electronic substrate clamped in place.

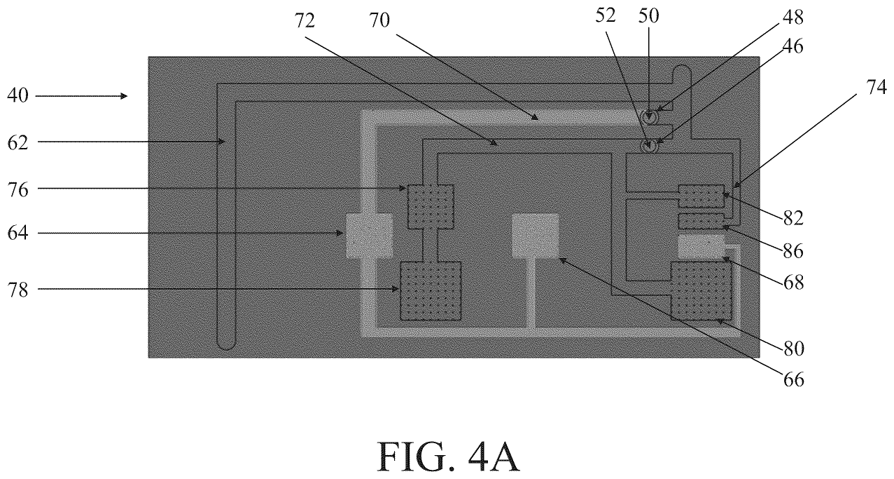

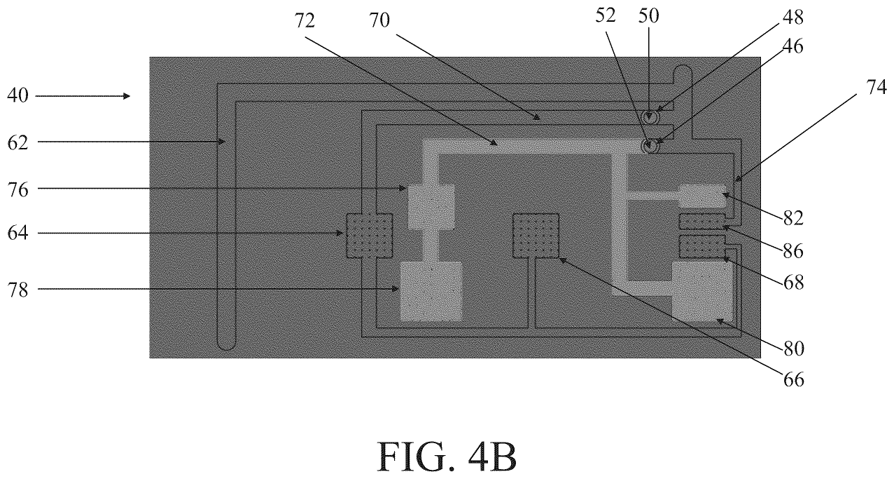

With additional reference to FIGS. 4A and 4B, to change the heating pattern provided by the areas or sets of holes 44 in the external surface 42, a first port 46 and a second port 48 are formed in the external surface 42 to connect with the air channel network 62. The ports 46, 48 may be threaded to receive a first set screw 50 and a second set screw 52, respectively. In certain examples, loosening the first set screw 50 permits hot air passing through the air channel network 62 (discussed in more detail below) to be channeled into a first heating pathway 70 (discussed in more detail below) to one set of holes 44 and loosening the second set screw 52 permits hot air passing through the air channel network 62 to be channeled into a second heating pathway 72 (discussed in more detail below) to another set of holes 44. Conversely, in certain examples, tightening the first set screw 50 blocks hot air passing through the air channel network from being channeled into the first heating pathway to one set of holes 44 and tightening the second set screw 52 blocks hot air passing through the air channel network from being channeled into the second heating pathway 72 to one set of holes 44. Loosening or tightening one of the set screws 50, 52 does not necessitate loosening or tightening the other set screw. In certain examples, the air channel network includes a third heating pathway 74 (discussed in more detail below) leading to a third set of holes 44 that receives the heated air regardless of any position of the set screws 50, 52 in their respective ports 46, 48.

FIG. 4A shows the air channel network 62 within the body 40 of the heated chuck plate. The air channel network 62 includes the first heating pathway 70, the second heating pathway 72, and the third heating pathway 74. As the air channel network 62 receives heated air, the air is channeled into one or more of the first heating pathway 70, the second heating pathway 72, and the third heating pathway 74. As shown in FIG. 4A, in the shown embodiment, the heated air passing through the air channel network 62 always passes into the third heating pathway 74 (and thereby a set of holes 86 included in the third heating pathway) because the pathway is not blocked by the set screws 50, 52. However, it is understood that embodiments include heated chuck plates with fewer or more than three heating pathways, and air channel networks that do not include any heating pathways that always pass the heated air through holes in the external surface of the heated chuck plate.

The air channel network 62 directs the heated air to a set of holes that correspond to a plurality of locations on the electronic substrate clamped into the heated chuck 38. A first set of holes is included in the first heating pathway 70, the first set of holes including a first grouping of holes 64, a second grouping of holes 66, and a third grouping of holes 68. The first grouping of holes 64 corresponds (i.e., directs air towards) to a first location on the electronic substrate clamped in the heated chuck 38. The second grouping of holes 66 corresponds to a second location on the electronic substrate. Similarly, the third grouping of holes 68 corresponds to a third location on the electronic substrate clamped in the heated chuck 38. By tightening the first set screw 50, the heated air is blocked from reaching any of the first grouping of holes 64, the second grouping of holes 66, and the third grouping of holes 68. By loosening the first set screw 50, as shown in FIG. 4A, the heated air is channeled to each of the first grouping of holes 64, the second grouping of holes 66, and the third grouping of holes 68. It is understood that a ‘set’ may include only one grouping and a ‘grouping’ may include only one hole.

A second set of holes is included in the second heating pathway 70, the second set including a fourth grouping of holes 76, a fifth grouping of holes 78, a sixth grouping of holes 80, and a seventh grouping of holes 82. As described above, each grouping corresponds to a different location on the electronic substrate clamped in the heated chuck 38. By tightening the second set screw 52, the heated air is blocked from reaching any of the fourth grouping of holes 76, the fifth grouping of holes 78, the sixth grouping of holes 80, and the seventh grouping of holes 82. By loosening the second set screw 52, as shown in FIG. 4B, the heated air is channeled to each of the fourth grouping of holes 76, the fifth grouping of holes 78, the sixth grouping of holes 80, and the seventh grouping of holes 82. It is understood than in addition to any reasonable number (i.e., that can practically be manufactured and/or fit within the heated chuck plate) of heating pathways, any reasonable number of hole groupings may be included in a given heating pathway.

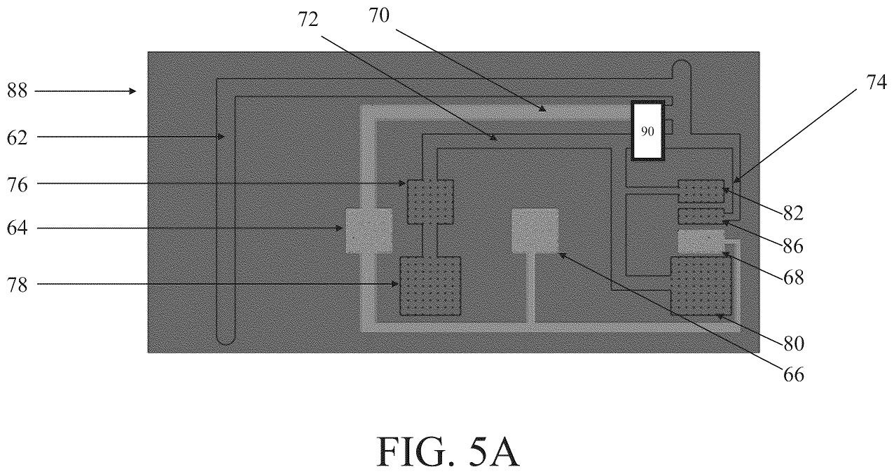

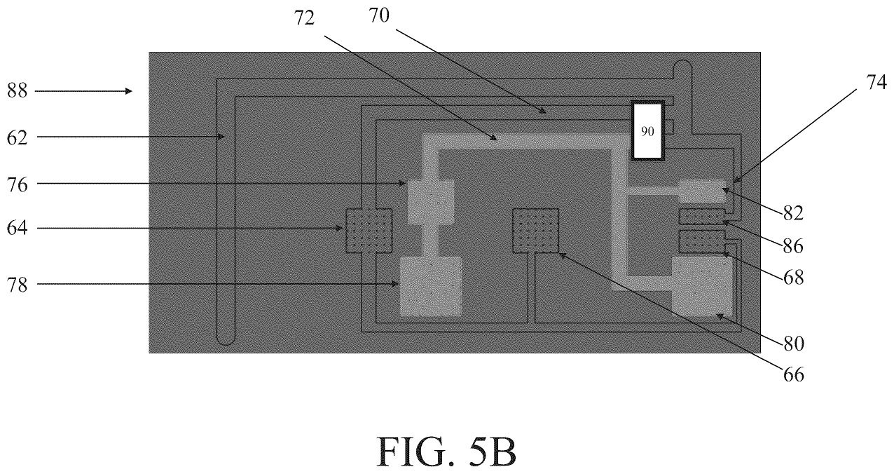

FIGS. 5A and 5B show a heated chuck plate generally indicated at 88 that differs from the heated chuck plate 40 at least in the manner in which the heated air is selectively channeled in to the first heating pathway 70 and the second heating pathway 72. Instead of the ports 46, 48 and set screws 50, 52 used in the heated chuck plate 40, the heated chuck plate 80 includes a valve 90. In a first configuration of the valve 90, the heated air is blocked from reaching the second heating pathway 72, as shown in FIG. 5A. In a second configuration of the valve 90, the heated air is blocked from reaching the first heating pathway 70, as shown in FIG. 5B. In certain examples, the valve 90 is electronically controlled by an external controller, e.g., controller 18, such that the valve 90 includes a motor that receives a control signal to switch between the first and second configurations. In other examples, the valve 90 is pneumatically controlled by the external controller such that the valve is in the first configuration responsive to a first pressure applied to the valve 90 and in the second configuration responsive to a second pressure different than the first pressure. In other examples, the valve is mechanically controlled such that one or more set screws, knobs, switches, or other mechanical actuators cause the valve to be in one of the two configurations.

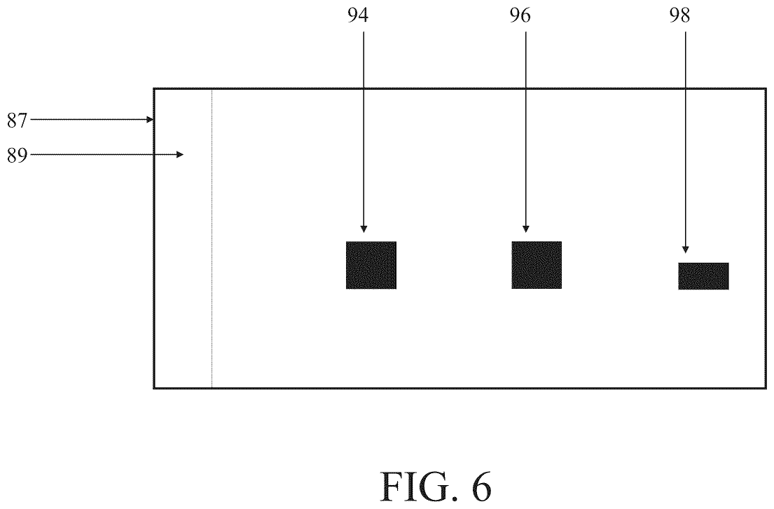

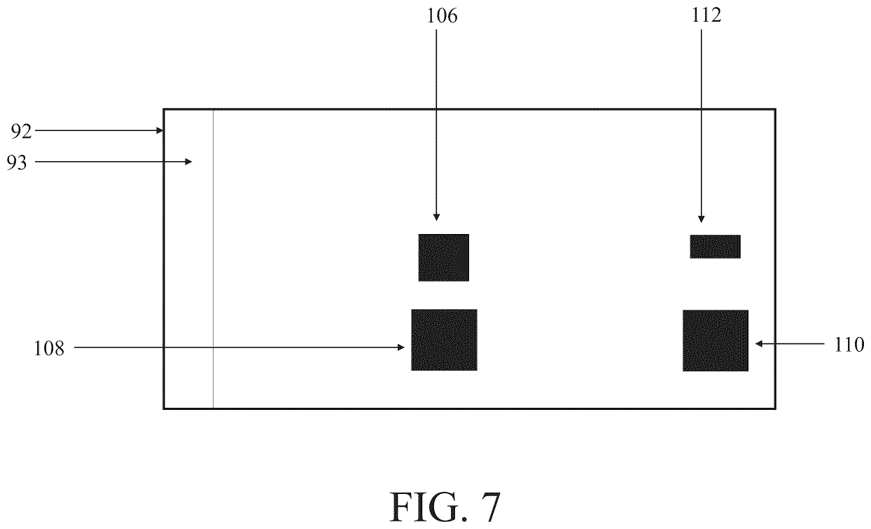

Referring to FIGS. 6 and 7, as an alternative or in addition to the ports 11 (FIG. 1) and the valve 90 (FIGS. 5A and 5B), a first mask 87 is provided as shown in FIG. 6 and a second mask 92 is provided as shown in FIG. 7. The first mask 87 and the second mask 92 are constructed from a material including one of metal, rubber, silicone, or mylar. It is understood that the masks 87, 92 described herein are not limited to these materials and can be made from any reasonable material that can withstand temperatures of around 150° C. or temperatures typically reached in solder dispensing applications.

The first mask 87 includes a first hole 94, a second hole 96, and a third hole 98, which correspond to the first grouping of holes 64, the second grouping of holes 66, and the third grouping of holes 68, respectively. It is understood that instead of a single, unitary hole, such as the hole 94, the masks 87, 92 may include groupings of holes for each of the locations on the electronic substrate. The holes in the first mask 87 may correspond in a one-to-one manner with the groupings of holes in FIGS. 4A-5B or may be different.

The second mask 92 includes a fourth hole 106, a fifth hole 108, a sixth hole 110, and a seventh hole 112, which correspond to the fourth grouping of holes 76, the fifth grouping of holes 78, the sixth grouping of holes 80, and the seventh grouping of holes 82, respectively. The holes in the second mask 92 may correspond in a one-to-one manner with the groupings of holes in FIGS. 4A-5B or may be different.

To restrict the heated air from reaching the electronic substrate via the first heating pathway 70, the first mask 87 is placed on the external surface 42. To restrict the heated air from reaching the electronic substrate via the second heating pathway 72, the second mask 92 is placed on the external surface 42.

To easily grasp the masks 87, 92 and avoid getting too close to the heated chuck plate 42, a grasping portion 89 is included in the first mask 87 and a grasping portion 93 is included in the second mask 92. The grasping portions 89, 93 of the masks 87, 92 extend over an edge of the external surface 42, making grasping the masks 87, 92 with the operator's fingers an easy gesture. The grasping portions 89, 93 of the masks 87, 92 may overhang any suitable edge of the surface 42.

According to certain embodiments, the first mask 87 and/or the second mask 92 is used with a heated chuck plate that does not have ports or set screws. In such embodiments, the air channel network provides the heated air to each set of groupings of holes and the particular set that needs to be blocked is accordingly blocked using an appropriate mask. For example, a heated chuck plate is identical the heated chuck plate 40, but the ports 46, 48 and set screws 50, 52 are absent, thereby connecting all the heating pathways 70, 72, 74 without obstruction. To select the first heating pathway 70, an operator places the second mask 92 on the external surface 42. To then select the second heating pathway 72 and block the first heating pathway 70 from heating the electronic substrate, the operator grasps the grasping portion 89 with his/her fingers and replaces the second mask 92 with the first mask 87.

The overall thickness of the first mask 87 and the second mask 92 is about 3 mm. In some examples, ‘about 3 mm’ is equivalent to 3 mm±.1 mm. It is understood that the thickness of the masks 87, 92 may vary depending upon different design parameters, such as the temperature of the heated air, the duration of heating the electronic substrate., and the particular material(s) chosen to construct the masks 87, 92.

In applications using infrared heat to heat an entire surface of the electronic substrate, it is understood that the masks 87, 92 can be configured to block the infrared heat from reaching locations on the substrate in a similar manner to the blockage of the heated air describe above.

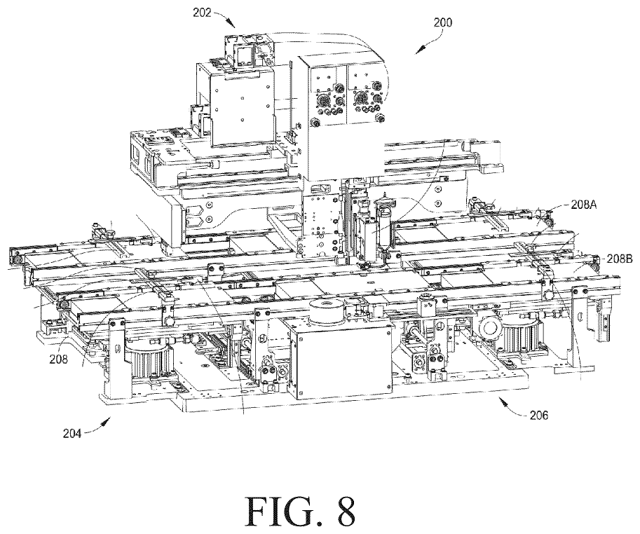

Referring to FIG. 8, a dispensing system is generally indicated at 200. As shown, the dispensing system 200 includes a dispense station, generally indicated at 202, a pre-heat station, generally indicated at 204, provided upstream before the dispense station, and a post-heat station, generally indicated at 206, provided downstream after the dispense station. The pre-heat station 204 defines a pre-heat zone, the dispense station 202 defines a dispense zone, and the post-heat station 206 defines a post-heat zone of the dispensing system 200. A conveyor 208 is provided to move an electronic substrate, such as substrate 12, from the pre-heat station 204 to the dispense station 202 and to the post-heat station 206 (left-to-right in FIG. 8). As shown, the conveyor 208 includes two lanes 208A, 208B to enable substrates to enter the dispense station more efficiently and at a greater rate.

The pre-heat station 204 is configured to heat the electronic substrate to an acceptable temperature for dispensing at the dispense station. The pre-heat station 204 can be configured to increase the temperature of the electronic substrate between a range of 20° C. to 200°° C. The post-heat station 206 is configured to reduce the temperature of the electronic substrate prior to being passed along to another processing station downstream from the dispensing system 200. As with the pre-heat station 204, the post-heat station can be configured to reduce the temperature of the electronic substrate between a range of 20° C. to 200° C.

In certain embodiments, one or more of the pre-heat station 204, the dispense station 202, and the post-heat station 206 is configured to use the heated chuck plates 40, 88 described above.

In one embodiment, the pre-heat station 204 and the post-heat station 206 can be part of the dispensing system 200 that includes the dispense station 202. In another embodiment, the dispensing system 200 can be configured to include the dispense station 202 only, and the pre-heat station 204 and/or the post-heat station 206 can be separate units that are assembled with the dispensing system, with the conveyor 208 extending through all three stations.

For each process zone, the operator selects a target temperature and tolerance range that the product needs to reach in order to be considered “ready.” “Ready” can mean that the product can move to the next conveyor zone or if in the dispense zone “ready” for the dispense process to begin. The other objective is to keep the substrate in the “ready” state, so when at temperature the machine automatically adjusts heat settings to keep the product within the desired tolerance range.

Embodiments herein include various heated chuck plates as well as systems and apparatus including the same. While the figures and described embodiments include specific examples of heated chuck plates, having particular numbers and arrangement of heating pathways, holes, and so forth, the scope of the disclosed subject matter is not limited to such arrangements. For example, as mentioned above, the heated chuck plates disclosed herein can be applied to other types of equipment, such as stencil printers. Thus, reference to an “apparatus” that is configured to deposit assembly material on an electronic substrate is meant to include dispensers and stencil printers.

Having thus described several aspects of at least one embodiment of this disclosure, it is to be appreciated various alterations, modifications, and improvements will readily occur to those skilled in the art. Such alterations, modifications, and improvements are intended to be part of this disclosure, and are intended to be within the spirit and scope of the disclosure. Accordingly, the foregoing description and drawings are by way of example only.

What is claimed is:

1. An apparatus for depositing an assembly material on an electronic substrate, the apparatus comprising:
a frame;
an assembly applicator coupled to the frame, the assembly applicator being configured to apply assembly material on the electronic substrate; and
a support assembly coupled to the frame, the support assembly being configured to support the electronic substrate, the support assembly including a heated chuck plate including
a body including an external surface, the body configured to secure the electronic substrate near the external surface, and
an air channel network configured to selectively direct heated air to a plurality of predetermined locations on the electronic substrate, the air channel network including
a first heating pathway configured to direct the heated air through the external surface and onto a first location of the plurality of predetermined locations, and
a second heating pathway configured to direct the heated air through the external surface and onto a second location of the plurality of predetermined locations.

2. The apparatus of claim 1, wherein
the air channel network includes a plurality of holes in the external surface of the body of the heated chuck plate,
the first heating pathway includes a first set of the plurality of holes, and
the second heating pathway includes a second set of the plurality of holes.

3. The apparatus of claim 2, wherein the first set of the plurality of holes includes a first grouping of the plurality of holes positioned to direct the heated air onto the first location of the plurality of predetermined locations on the electronic substrate, and
the second set of the plurality of holes includes a second grouping of the plurality of holes positioned to direct the heated air onto the second location of the plurality of predetermined locations on the electronic substrate.

4. The apparatus of claim 1, wherein the air channel network further includes at least one port configured to selectively permit the heated air into one of the first heating pathway and the second heating pathway.

5. The apparatus of claim 4, wherein
the at least one port includes a first port configured to selectively permit the heated air into the first heating pathway and a second port configured to selectively permit the heated air into the second heating pathway.

6. The apparatus of claim 5, wherein
the first port is configured to receive a first set screw, the first set screw blocking the heated air from traveling through the first heating pathway when the first set screw is tightened and permitting the heated air to travel through the first heating pathway when the first set screw is loosened, and
the second port is configured to receive a second set screw, the second set screw blocking the heated air from traveling through the second heating pathway when the second set screw is tightened and permitting the heated air to travel through the second heating pathway when the second set screw is loosened.

7. The apparatus of claim 6, wherein the air channel network further includes a third heating pathway configured to receive the heated air regardless of any position of the first set screw in the first port and regardless of any position of the second set screw in the second port.

8. The apparatus of claim 1, further comprising a first mask including at least one hole positioned in the first mask to direct the heated air from the first heating pathway onto at least one location of the plurality of predetermined locations on the electronic substrate.

9. The apparatus of claim 8, wherein the first mask, except for the at least one hole, is configured to block the heated air from directly encountering the electronic substrate.

10. The apparatus of claim 8, wherein the at least one hole includes
a first hole positioned in the first mask to direct the heated air from the first heating pathway onto the first location of plurality of predetermined locations on the electronic substrate, and
a second hole positioned in the first mask to direct the heated air from the second heating pathway onto the second location of the one or more predetermined locations on the electronic substrate.

11. The apparatus of claim 8, wherein the first mask includes a grasping portion for removing the first mask from the external surface, the grasping portion extending over an edge of the external surface.

12. The apparatus of claim 8, further comprising a second mask including at least one hole positioned in the second mask to direct the heated air from the second heating pathway onto at least one location of the plurality of predetermined locations on the electronic substrate.

13. A heated chuck plate comprising:
a body including an external surface, the body configured to secure an electronics assembly near the external surface; and
an air channel network configured to selectively direct heated air to a plurality of predetermined locations on the electronics assembly, the air channel network including:
a first heating pathway configured to direct the heated air through the external surface and onto a first location of the plurality of predetermined locations; and
a second heating pathway configured to direct the heated air through the external surface and onto a second location of the plurality of predetermined locations.

14. The heated chuck plate of claim 13, wherein
the air channel network includes a plurality of holes in the external surface of the body of the heated chuck plate,
the first heating pathway includes a first set of the plurality of holes, and
the second heating pathway includes a second set of the plurality of holes.

15. The heated chuck plate of claim 14, wherein
the first set of the plurality of holes includes a first grouping of the plurality of holes positioned to direct the heated air onto the first location of the plurality of predetermined locations on the electronics assembly, and
the second set of the plurality of holes includes a second grouping of the plurality of holes positioned to direct the heated air onto the second location of the plurality of predetermined locations on the electronics assembly.

16. The heated chuck plate of claim 13, wherein the air channel network further includes at least one port configured to selectively permit the heated air into one of the first heating pathway and the second heating pathway.

17. The heated chuck plate of claim 16, wherein the at least one port includes a first port configured to selectively permit the heated air into the first heating pathway and a second port configured to selectively permit the heated air into the second heating pathway.

18. The heated chuck plate of claim 17, wherein
the first port is configured to receive a first set screw, the first set screw blocking the heated air from traveling through the first heating pathway when the first set screw is tightened and permitting the heated air to travel through the first heating pathway when the first set screw is loosened, and
the second port is configured to receive a second set screw, the second set screw blocking the heated air from traveling through the second heating pathway when the second set screw is tightened and permitting the heated air to travel through the second heating pathway when the second set screw is loosened.

19. The heated chuck plate of claim 18, wherein the air channel network further includes a third heating pathway configured to receive the heated air regardless of any position of the first set screw in the first port and regardless of any position of the second set screw in the second port.

20. The heated chuck plate of claim 13, further comprising a valve configured to selectively direct the heated air into one of the first heating pathway and the second heating pathway.
